(19) United States
(12) Patent Application Publication
(10) Pub. No.: US 2026/0363357 A1
(43) Pub. Date: Nov. 19, 2026

(54) CHARGING CASE FOR AEROSOL-GENERATING DEVICE WITH REMOVABLE BATTERY COMPARTMENT COVER

(71) Applicant: Philip Morris Products S.A., Neuchatel (CH)

(72) Inventors: Walter Fajardo CAMOTA, Hong Kong (HK); Sander BROUWER, Lausanne (CH)

(73) Assignee: Philip Morris Products S.A., Neuchatel (CH)

(21) Appl. No.: 19/139,477

(22) PCT Filed: Dec. 22, 2023
(86) PCT No.: PCT/EP2023/087712

§ 371 Date: Jun. 16, 2025

(30) Foreign Application Priority Data
Dec. 30, 2022 (EP) 22217417.9

(51) Int. Cl. A24F 40/95; H01M 10/46; H01M 50/247; H01M 50/271; H02J 7/70; H02J 50/10

(52) U.S. Cl. CPC A24F 40/95; H01M 10/46; H01M 50/247; H01M 50/271; H02J 7/731; H02J 50/10; H01M 2220/30

(57) ABSTRACT

A charging case for an aerosol-generating device is provided, including: a case body extending along an axial direction and defining a battery compartment and a docking compartment, the docking compartment being configured to receive an aerosol-generating device, and the battery compartment being configured to removably receive a charging case battery; a battery compartment cover reversibly operable between a closed state and an open state, the battery compartment cover being configured to cover a battery exchange opening of the battery compartment in the closed state and to allow access to the battery compartment through the battery exchange opening in the open state; and an outer cover including a flexible flap portion configured to reversibly wrap around the case body, the outer cover being configured to form at least part of an outer surface of the charging case, and the outer cover being further configured to cover the battery compartment cover.

The present disclosure relates to charging cases for aerosol-generating devices.

Different types of aerosol-generating devices are known. For example, aerosol-generating devices according to a heat-not-burn type generally comprise a device battery, control electronics, and an electric heater for heating an aerosol-generating article to generate aerosol for consumption by a user. The aerosol-generating article may comprise an aerosol-forming substrate, such as a tobacco segment or a tobacco plug, and the electric heater contained within the aerosol-generating device penetrates into or is located around the aerosol-forming substrate, when the aerosol-generating article is received in the aerosol-generating device. According to another example, aerosol-generating devices according to a vaporizer type may comprise a device battery to heat aerosol-generating liquid from a cartridge to provide aerosol for consumption by a user.

WO 2021/074420 discloses a holder for an elongate aerosol-generating device. The holder defines a docking space for accommodating the aerosol-generating device. The aerosol-generating device can be accommodated in the docking space for protection and for recharging of a device battery of the aerosol-generating device with power from a primary battery of the holder. The holder comprises a cover that is moveable between a covering position, in which the cover covers at least a portion of the docking space, and a non-covering position.

WO 2021/089304 A1 discloses a holder for an aerosol-generating device. The holder has a docking space for accommodating a longitudinal dimension of the aerosol-generating device. The holder comprises a primary battery for charging a device battery of the aerosol-generating device.

According to a first aspect of the present invention, there is provided a charging case for an aerosol-generating device. The charging case comprises a case body and a battery compartment cover. The case body extends along an axial direction. The case body defines a battery compartment and a docking compartment. The docking compartment is configured to receive an aerosol-generating device. The battery compartment is configured to removably receive a charging case battery. The battery compartment cover is reversibly operable between a closed state and an open state. The battery compartment cover is configured to cover a battery exchange opening of the battery compartment in the closed state. The battery compartment cover is configured to allow access to the battery compartment through the battery exchange opening in the open state.

The charging case may be a portable charging case for storing an aerosol-generating device between uses. The charging case may be configured to protect an aerosol-generating device received in the docking compartment.

The charging case may be configured to electrically charge a device battery of an aerosol-generating device received in the docking compartment with power from the charging case battery.

In the closed state, the battery compartment cover may protect an inside of the battery compartment. In the closed state, the battery compartment cover may at least partially prevent foreign matter, such as dust or other contaminants, from entering the battery compartment. In the closed state, the battery compartment cover may hide an inside of the battery compartment. In the closed state, the battery compartment cover may prevent the charging case battery from falling out of the battery compartment through the battery exchange opening.

In the open state, a charging case battery arranged in the battery compartment may be removable from the battery compartment through the battery exchange opening. In the open state, a charging case battery may be insertable into the battery compartment through the battery exchange opening.

Reversibly operating the battery compartment cover between the closed state and the open state may comprise reversibly bringing the battery compartment cover from the closed state to the open state. Reversibly operating the battery compartment between the closed state and the open state may comprise reversibly operating the battery compartment cover from the open state to the closed state. The battery compartment cover may be configured to be operable between the closed state and the open state multiple times without the need for replacement components. The battery compartment cover may be operable between the closed state and the open state in a non-destructive manner.

The battery compartment cover may be configured to allow exchanging or replacing a charging case battery arranged in the battery compartment through the battery exchange opening.

The charging case may comprise the charging case battery. The charging case battery may be removably arranged in the battery compartment. The charging case battery may be configured to be replaced or exchanged through the battery exchange opening. Replacing or exchanging the charging case battery may increase a service live of the charging case.

The charging case battery may be provided free of a fixed connection to the charging case. The charging case battery may be configured to be removed from the battery compartment in a non-destructive manner. The charging case battery may be provided in the battery compartment without being connected to other parts of the charging case by way of an adhesive or a glue.

The charging case battery may be a rechargeable battery. The charging case battery may be configured to be recharged, while being arranged in the battery compartment.

The charging case battery may be an alkaline battery, or a nickel metal hydride (NIMH) battery, or a lithium ion battery, for example.

The charging case may comprise an electric battery interface. The electric battery interface may be provided in the battery compartment. The charging case battery may be electrically connected to the electric battery interface, while being arranged in the battery compartment. The charging case battery may be configured to be reversibly disconnected from the electric battery interface. The charging case battery may be electrically connected to the electric battery interface free of a fixed connection between the charging case battery and electric battery interface, for example free of a connection by soldering or welding or gluing.

The electric battery interface may comprise one or more contact structures. The one or more contact structures may be configured to be connected to one or more contacts of the charging case battery, in particular by way of a snap-fit connection. The one or more contact structures may be biased towards engaging one or more contacts of the charging case battery.

The charging case may comprise an electric device interface. The electric device interface may be provided in the docking compartment. The electric device interface may be configured to electrically connect to an aerosol-generating device received in the docking compartment. The electric device interface may be configured to charge a device battery of the aerosol-generating device with electrical energy from the charging case battery.

The electric battery interface and electric device interface may be electrically connected to each other to charge a device battery of an aerosol-generating device received in the docking compartment with electric current from the charging case battery.

Operating the battery compartment cover between the closed state and the open state may comprise changing a relative positioning between the case body and the battery compartment cover.

Operating the battery compartment cover from the closed state to the open state may comprise removing the battery compartment cover from the case body. In the open state, the battery compartment cover may be removed from the case body.

Operating the battery compartment cover from the open state to the closed state may comprise attaching the battery compartment cover to the case body. In the closed state, the battery compartment cover may be attached to the case body.

The battery compartment cover may be attached to the case body by a snap-fit connection.

The battery compartment cover may be attached to the case body by one or more attachment elements. The one or more attachment elements may be configured to allow repeated removal and attachment of the battery compartment cover to the case body.

The one or more attachment elements may comprise one or more attachment elements that are separate from both the case body and the battery compartment cover. For example, the one or more attachment elements may comprise screws or clips. The one or more attachment elements may be configured to extend through one or more respective openings in the battery compartment cover. The one or more attachment elements may be configured to be held in a receiving structure of the case body.

The one or more attachment elements may comprise one or more structures provided at the battery compartment cover or at the case body. The one or more structures may be configured to engage one or more counter-structures provided at the other one of the battery compartment cover and the case body. For example, the one or more structures may comprise hook structures. For example, the one or more counter-structures may comprise recesses. The one or more structures and one or more counter-structures may together form a snap-fit connection.

The battery compartment cover may be attached to the case body both in the closed state and in the open state. Operating the battery compartment cover between the closed state and the open state may comprise rotating the battery compartment cover about a cover rotation axis. The battery compartment cover may be attached to the case body at the cover rotation axis. The cover rotation axis may extend in parallel to the axial direction, for example. The battery compartment cover may be formed as a door of the battery compartment.

In the closed state, at least 50 percent, or at least 60 percent, or at least 70 percent, or at least 80 percent, or at least 90 percent of an area of the battery compartment cover may be arranged directly above the battery exchange opening. If the battery compartment cover is shaped and sized so that most of the battery compartment cover actually covers the battery exchange opening, unnecessary removal of larger parts to access the battery compartment may be avoided.

In the closed state, a maximum extension of the battery compartment cover beyond the battery exchange opening may be less than or equal to 40 millimeters, or 30 millimeters, or 25 millimeters, or 20 millimeters, or 15 millimeters, or 10 millimeters, or 5 millimeters.

The battery compartment cover may be plate-shaped. The battery compartment cover may be flat or curved.

A dimension of the battery compartment cover along its main extension direction may be between 1 centimeter and 10 centimeters, or between 2 centimeters and 10 centimeters, or between 2 centimeters and 8 centimeters, or between 3 centimeters and 8 centimeters, or between 3 centimeters and 7 centimeters, or between 4 centimeters and 5 centimeters, for example. The main extension direction of the battery compartment may be parallel to the axial direction.

The battery compartment cover may have a curvature in a sectional plane perpendicular to a longitudinal direction of the battery compartment cover. The battery compartment cover may be non-curved along the longitudinal direction of the battery compartment cover. The longitudinal direction of the battery compartment cover may, at least in the closed state, extend in parallel to the axial direction.

The battery compartment cover may have a shape that conforms to a shape of the case body. The battery compartment cover and the case body may be configured to together form a smooth shape.

A surface of the case body may comprise a recessed area. In the closed state, the battery compartment cover may be provided in the recessed area. An extension of the battery compartment cover above the surface of the case body may be reduced due to the battery compartment cover being provided in the recessed area.

A shape of the recessed area may correspond to a shape of the battery compartment cover. The recessed area may facilitate obtaining a correct arrangement of the battery compartment cover with respect to the case body.

The battery compartment cover may lie at least essentially flush with an adjacent surface of the case body in the closed state. A height difference between the battery compartment cover and an adjacent surface of the case body in the closed state may be less than 3 millimeters, or less than 2 millimeters, or less than 1 millimeter, or less than 0.5 millimeter, or less than 0.3 millimeter in the closed state.

The case body may comprise a floor surface and a ceiling surface. The floor surface and the ceiling surface may delimit and extension of the battery compartment along the axial direction. The floor surface and ceiling surface may face each other. The floor surface and the ceiling surface may form a part of an inner wall of the battery compartment.

The case body may comprise a side surface forming an inner wall section of the battery compartment over an angular extension around a center axis of the battery compartment of at least 60 degrees, or at least 90 degrees, or at least 120 degrees, or at least 180 degrees, or at least 240 degrees. The center axis may be parallel to the axial direction.

The charging case may comprise a controller. The controller may comprise a printed circuit board. The battery compartment may be separated from one or both of the controller and the printed circuit board by a wall of the charging case.

When the battery is received in the battery compartment, at least 40 percent, or at least 50 percent, or at least 60 percent, or at least 70 percent, or at least 80 percent, or at least 90 percent of a volume of the battery compartment may be occupied by the charging case battery.

The battery compartment may be accessible through the docking compartment. If the battery compartment is accessible through the docking compartment, it may not be necessary to provide an additional access point to the battery compartment outside the docking compartment. Thus, accessibility of the battery compartment may be provided without negatively influencing an outward appearance of the charging case.

The battery compartment cover may be accessible through the docking compartment.

One or both of the battery compartment cover and the charging case battery may be configured to be removed from the case body through the docking compartment.

One or both of the battery compartment cover and the charging case battery may be configured to be removed through the docking compartment after removal of the aerosol-generating device from the storage compartment.

The battery exchange opening may be formed in a wall defining an inner surface of the docking compartment. The wall may be a wall of the case body.

The battery compartment cover may separate the battery compartment from the docking compartment in the closed state.

A charging antenna for wirelessly charging the charging case battery may be integrated in the battery compartment cover. The charging antenna may be an integral part of the battery compartment cover. The charging antenna may be electrically connected to the electric battery interface, at least in the closed state of the battery compartment cover. The charging antenna may be electrically connected to the charging case battery, at least in the closed state of the battery compartment cover. The charging antenna may be configured to receive a wireless power transmission from an external charging station. Providing the charging antenna integrated in the battery compartment cover may save space in other parts of the charging case.

The battery compartment cover may comprise a battery compartment cover electric interface electrically connected to the charging antenna in the battery compartment cover.

The case body may comprise a case body electric interface configured to be electrically connected to the charging case battery. The case body electric interface may be electrically connected to the electric battery interface.

The charging case may comprise an electrical connector electrically connecting the battery compartment cover electric interface to the case body electric interface to supply power from the charging antenna integrated in the battery compartment cover to the charging case battery. The electrical connector may electrically connect the battery compartment cover electric interface to the case body electric interface in the closed state of the battery compartment cover. The electrical connector may be configured to electrically connect the battery compartment cover electric interface to the case body electric interface both in the closed state and the open state of the battery compartment cover.

The electrical connector may be a flexible connector. The electrical connector may be a flex connector. The electrical connector may be a flat cable connector.

The battery compartment cover may form at least part of an outer appearance of the charging case. The battery compartment cover may be directly accessibly from outside the charging case.

The battery compartment cover may comprise a user interface. This user interface may comprise a display. The user interface may comprise a push button.

The battery compartment cover may comprise a data port enabling data transmission between an external device and the charging case. The data port may comprise a USB port, in particular a USB-C port, for example.

The battery compartment cover may comprise a metal material or may be formed of a metal material. The metal material may be aluminum, or may comprise aluminum.

The battery compartment cover may comprise end portions covering opposing ends of the case body with respect to the axial direction. The end portions may form part of an outer appearance of the charging case.

At least one of the end portions may have a curved side surface defining at least a part of a side surface of the charging case extending around the axial direction.

The battery compartment cover may have an axially extending cover portion connecting the end portions. The axially extending cover portion may be curved around the axial direction.

The battery compartment cover may define a cavity receiving the battery compartment in the closed state of the battery compartment cover.

The case body may be at least partially received in the battery compartment cover, in particular in the cavity of the battery compartment cover, in the closed state of the battery compartment cover.

Operating the battery compartment cover from the closed state to the open state may comprise partially or fully removing the case body from the cavity. By removing the case body from the cavity, the battery compartment, in particular the battery exchange opening of the battery compartment, may become accessible enable removal of the charging case battery from the battery compartment.

Operating the battery compartment cover from the open state to the closed state may comprise partially or fully inserting the case body into the cavity. By inserting the case body into the cavity, the battery compartment, in particular the battery exchange opening of the battery compartment, may become covered by the battery compartment cover.

The charging case may further comprise an outer cover. The outer cover may be configured to form at least part of an outer surface of the charging case.

The outer cover may be configured to cover the battery compartment cover. The outer cover may be configured to fully cover the battery compartment cover. The outer cover may hide the battery compartment cover. The outer cover may protect the battery compartment cover. The outer cover may reduce a likelihood that foreign matter, such as dust or liquid, enters through a potential gap between the battery compartment cover and the case body.

The outer cover may be configured to lie over the battery compartment cover in contact with the battery compartment cover.

The outer cover may be removably attached to the case body. The outer cover may be reversibly attachable to the case body. Removing the outer cover may facilitate accessing the battery compartment cover. The outer cover may comprise an attachment portion removably attached to the case body. The outer cover, in particular the attachment portion of the outer cover, may be removably attached to the case body by magnetic interaction between the outer cover and the case body. In particular, the outer cover may be attached to the case body by magnetic interaction between the attachment portion of the outer cover and the case body. One or more magnets may be provided at one or both of the outer cover and the case body to removably attach the outer cover to the case body.

The outer cover may be configured to reversibly wrap around the case body from one side of the case body around the opposing side of the case body back to the one side of the case body. The outer cover may provide a clean and unitary appearance of the charging case.

The outer cover may comprise a flexible flap portion. The flexible flap portion may be configured to reversibly wrap around the case body. The flexible flap portion may be configured to wrap around the case body so as to be in contact with the case body. The flexible flap portion may be configured to bend around the case body to assume a shape corresponding to the shape of the case body. The flexible flap portion may be configured to reversibly wrap around the case body around an axis parallel to the axial direction. The flexible flap portion may be configured to reversibly wrap around part of a circumference of the case body. The flexible flap portion may be configured to reversibly wrap around a full circumference of the case body. The flexible flap portion may be configured to reversibly wrap around the case body from one side of the case body around the opposing side of the case body back to the one side of the case body.

The outer cover, in particular the flexible flap portion of the outer cover, may have a free end. The free end may be configured to be attached to the case body to bring the outer cover into a storage configuration. The free end may be configured to be separated from the case body to bring the outer cover into an access configuration.

The free end may be spaced apart from the attachment portion of the outer cover. The outer cover may be attached to the case body, in particular attached to the case body at the attachment portion of the outer cover, both in the storage configuration and in the access configuration.

The outer cover may be configured to cover a loading opening of the docking compartment in the storage configuration. In the storage configuration, the outer cover may be configured to cover an aerosol-generating device received in the docking compartment. In the storage configuration, the outer cover may protect an aerosol-generating device received in the docking compartment. In the storage configuration, the outer cover may prevent an aerosol-generating device from falling out of the storage compartment.

In the access configuration, the loading opening of the docking compartment may be uncovered. The outer cover may be configured not to cover the loading opening of the docking compartment in the access configuration. In the assess configuration, an aerosol-generating device may be insertable into the docking compartment through the loading opening. In the assess configuration, an aerosol-generating device may be removable from the docking compartment through the loading opening.

The outer cover may be configured to extend around the case body over at least 50 percent, or at least 60 percent, or at least 70 percent, or at least 80 percent, or at least 90 percent, or at least 100 percent of a circumference of the case body. The outer cover may be configured to extend around the case body over between 95 percent and 99 percent of a circumference of the case body. The circumference of the case body may be around the axial direction. The outer cover may extend around the case body over a range of at least 180 degrees, or at least 210 degrees, or at least 240 degrees, or at least 270 degrees, or at least 300 degrees, or at least 330 degrees, or at least 360 degrees around an axis parallel to the axial direction.

The charging antenna for wirelessly charging the charging case battery may be integrated in the outer cover. The charging antenna may be electrically connected to the electric battery interface. The charging antenna may be electrically connected to the charging case battery. The charging antenna may be configured to receive a wireless power transmission from an external charging station. Providing the charging antenna integrated in the outer cover may save space in other parts of the charging case.

The outer cover may comprise a rigid portion. The rigid portion may be configured to maintain its shape. The rigid portion may be stiff. The rigid portion may lie above the battery compartment opening.

The rigid portion may be provided between the attachment portion and the flexible flap portion. The rigid portion may be provided between the attachment portion and the free end. The attachment portion may be provided between the rigid portion and the flexible flap portion. The attachment portion may be provided between the rigid portion and the free end.

The outer cover may comprise a second flexible flap portion. The second flexible flap portion may be provided between the connection portion and the rigid cover portion. The rigid cover portion may be provided between the flexible flap portion and the second flexible flap portion.

A charging antenna for wirelessly charging the charging case battery may be integrated in the outer cover. The charging antenna may extend over an area of the outer cover of at least 5 square centimeters, or at least 8 square centimeters, or at least 10 square centimeters, or at least 15 square centimeters.

The charging antenna may be integrated in the flexible flap portion of the outer cover. The charging antenna may be integrated in the rigid portion of the outer cover. In the rigid portion, the likelihood of damage to the charging antenna due to bending of the outer cover may be reduced. The outer cover may comprise a stiffening layer where the charging antenna is integrated in the outer cover. The stiffening layer may be integrated in the outer cover. The stiffening layer may locally modify a stiffness of the outer cover so that the charging antenna cannot be or can only be minimally bent. The stiffening layer may help preventing damage to the charging antenna, in particular preventing breakage of windings of an antenna coil.

The outer cover may comprise a heat dissipation layer. The heat dissipation layer may be configured to receive heat from the charging antenna to prevent overheating of the charging antenna.

A stack of layers may be embedded into the outer cover. The stack of layers may include the stiffening layer facing the case body, the charging antenna on top of the stiffing layer, and the heat dissipation layer on top of the charging antenna. The stack may have a substantially rectangular shape with rounded corners. The heat dissipation layer may be the layer of the stack of layers that is closest to the outside environment.

The stack may fit to a side surface of the case body. The side surface may be without curvature around the axial direction.

In an embodiment, only parts of the outer cover that are on an axial round side edge of the outer cover are flexible.

In addition or as an alternative to the heat dissipation layer, the outer cover may comprise an energy dissipating electric circuit. The energy dissipating electric circuit may be configured to dissipate energy from the charging antenna. The energy dissipating electric circuit may comprise one or more resistive elements.

The outer cover may comprise an outer cover electric interface. The outer cover electric interface may be electrically connected to the charging antenna. The case body may comprise an antenna connection electric interface. The antenna connection electric interface may be configured to electrically connect to the outer cover electric interface.

The charging case may further comprise a housing part. The housing part may be attached to the case body. The housing part may form at least part of an outer appearance of the charging case.

The housing part may comprise end cover portions. The end cover portions may cover opposing ends of the case body with respect to the axial direction. The end cover portions may comprise two end cover portions. The end cover portions may extend in parallel to each other. The end cover portions may extend in perpendicular to the axial direction. The end cover portions may have essentially elliptic shapes, or essentially round shapes, or essentially rectangular shapes, for example.

The end cover portions may each comprise an end surface visible, when viewing the charging case along or against the axial direction.

At least one of the end cover portions may comprise a rounded edge circumferentially extending around the axial direction. The rounded edge may have a reduced susceptibility to being damaged as compared to a sharp edge, for example.

At least one of the end cover portions may have a side surface defining at least a part of a side surface of the charging case extending around the axial direction. The side surface of the at least one end cover portion may be visible, when viewing the charging case in a viewing direction perpendicular to the axial direction.

The side surface of the at least one end cover portion may be curved, in particular outwardly curved. The side surface of the at least one end cover portion may be spherically shaped. A cross-section of the side surface of the at least one end cover portion in a sectional plane parallel to the axial direction may be curved, in particular outwardly curved. A curvature of the side surface of the at least one end cover portion in a sectional plane parallel to the axial direction may be the same along an entire circumference of the charging case.

A shape of the side surface of the at least one end cover portion may smoothly transition into the end surface of the at least one end cover portion.

The side surface of the at least one end cover portion may form an edge of the charging case. The edge may be rounded.

A display receiving cavity may be provided in at least one of the end cover portions. The display receiving cavity may, for example, be partly or fully provided in the side surface of the at least one end cover portion. The display receiving cavity may be exclusively provided in the side surface of the at least one end cover portion. A substantial area of the at least one end cover portion may be covered by the display receiving cavity. For example, the display receiving cavity may be arranged in a center of the at least one end cover portion. There may be a small surrounding border made of the at least one end cover portion around the display receiving cavity.

The charging case may comprise a display. The display may be provided in the display receiving cavity.

The display may be provided partly or fully provided in the side surface of the at least one end cover portion. A substantial area of the at least one end cover portion may be covered by the display. For example, the display may be arranged in a center of the at least one end cover portion. There may be a small surrounding border made of the at least one end cover portion around the display. The entire end cover portion may be covered by the display.

The display may be a curved display. A curvature of the display may be at least substantially the same as a curvature of the side surface of the at least one end cover portion. The display may lie flush with an adjacent surface of the at least one end cover portion.

The display may comprise a fiberoptic element. The display may be configured to indicate a charging state of the charging case battery or a charging state of a device battery of an aerosol-generating device received in the docking compartment. The display may be configured to indicate other information related to an operational status of the aerosol generating system.

The housing part may comprise an axially extending connection portion. The extending connection portion may connect the end portions. The connection portion may extend around the axial direction over at most 90 degrees, or at most 60 degrees, or at most 30 degrees, or at most 20 degrees, or at most 10 degrees.

The connection portion may cover the case body. The connection portion may cover at least any portion of the case body that is not covered by the outer cover, at least in the storage configuration of the outer cover.

Two opposing ends of the outer cover along a circumferential direction of the charging case may be spaced apart from each other in the storage configuration of the outer cover. The housing part, in particular the connection portion of the housing part, may be visible through a gap between the opposing ends of the outer cover. The gap may have a width between 1 millimeter and 25 millimeters, or between 1 millimeter and 20 millimeters, or between 1 millimeter and 15 millimeters, or between 1 millimeter and 10 millimeters, or between 1 millimeter and 7 millimeters, or between 1 millimeter and 5 millimeters, or between 1 millimeter and 3 millimeters. The width of the gap may be a width in a circumferential direction. The housing part, in particular the connection portion of the housing part may fully fill the gap.

The housing part may comprise a metal material. The housing part may consist of a metal material. The housing part may be formed as one piece. The housing part may be formed as one metal piece. The metal material may comprise aluminum. The material may be aluminum or an alloy of aluminum.

According to a second aspect of the present invention, there is provided a method for replacing a battery of a charging case for an aerosol-generating device. The method comprises steps a) to d). Step a) comprises removing a battery compartment cover from a case body of the charging case, thereby uncovering a battery exchange opening of a battery compartment of the charging case. Step b) comprises removing a charging case battery from the battery compartment through the battery exchange opening. Step c) comprises inserting a replacement charging case battery into the battery compartment through the battery exchange opening. Step d) comprises re-attaching the battery compartment cover to the case body to close the battery compartment.

Steps a) to d) may be carried out in alphabetical order.

Removing the battery compartment cover from the case body may comprise disengaging one or more attachment elements fixing the battery compartment cover to the case body.

At least one of the battery compartment cover and the charging case battery may be removed through a loading opening configured to insert an aerosol-generating device into a docking compartment of the charging case. The battery compartment cover may be accessed through the docking compartment of the charging case.

The method may further comprise removing an outer cover of the charging case from the case body to uncover the battery compartment cover. The outer cover may comprise a flexible flap portion configured to reversibly wrap around the case body

Removing the outer cover of the charging case may comprise overcoming magnetic attraction holding the outer cover at the case body.

Removing the battery compartment cover from the case body may comprise removing the case body from a cavity of the battery compartment cover.

According to a third aspect of the present invention, there is provided a use of an outer cover for covering a removable battery compartment cover of a charging case for an aerosol-generating device.

The outer cover may define an outer appearance of the charging case over a full circumference of the charging case around an axial direction.

The outer cover may be removably attached to a case body defining the battery compartment.

The outer cover may comprise a flexible flap portion. The flexible flap portion may cover a loading opening of a docking space of the charging case. The docking space may be configured to receive an aerosol-generating device to be charged.

The outer cover may comprise a rigid cover portion. The rigid cover portion may cover the battery compartment cover.

The rigid cover portion and the flexible flap portion together may define a continuous outer surface of the charging case.

According to a fourth aspect of the present invention, there is provided a charging case for an aerosol-generating device. The charging case comprises a case body, a charging case battery and an outer cover. The case body extends along an axial direction. The case body defines a docking compartment configured to receive an aerosol-generating device. The outer cover is configured to form at least part of an outer surface of the charging case. A charging antenna for wirelessly charging the charging case battery is integrated in the outer cover.

The charging case battery may be received in a battery compartment defined by the case body.

The outer cover may be removably attached to the case body. The outer cover may be removably attached to the case body at an attachment portion of the outer cover. The charging antenna may be replaceable by replacing the outer cover.

The outer cover may comprise a flexible flap portion. The flexible flap portion may be configured to reversibly wrap around the case body.

The outer cover, in particular the flexible flap portion of the outer cover, may have a free end. The free end may be configured to be attached to the case body to bring the outer cover in to a storage configuration. The free end may be configured to be separated from the case body to bring the outer cover into an access configuration. The attachment portion of the outer cover may be attached to the case body both in the storage configuration and in the access configuration.

The outer cover may be configured to cover a loading opening of the docking compartment in the storage configuration. The loading opening of the docking compartment may be uncovered in the access configuration.

The charging antenna may be provided in the flexible flap portion.

The charging antenna may be provided in a rigid portion of the outer cover.

The outer cover may comprise a stiffening layer where the charging antenna is integrated in the outer cover. The stiffening layer may be integrated in the outer cover. The stiffening layer may locally modify a stiffness of the outer cover so that the charging antenna cannot be or can only be minimally bent. The stiffening layer may help preventing damage to the charging antenna, in particular preventing breakage of windings of an antenna coil.

The outer cover may comprise a heat dissipation layer. The heat dissipation layer may be configured to receive heat from the charging antenna to prevent overheating of the charging antenna.

A stack of layers may be embedded into the outer cover. The stack of layers may include the stiffening layer facing the case body, the charging antenna on top of the stiffing layer, and the heat dissipation layer on top of the charging antenna. The stack may have a substantially rectangular shape with rounded corners.

The stack may fit to a side surface of the case body. The side surface may be without curvature around the axial direction.

In an embodiment, only parts of the outer cover that are on an axial round side edge of the outer cover are flexible.

In addition or as an alternative to the heat dissipation layer, the outer cover may comprise an energy dissipating electric circuit. The energy dissipating electric circuit may be configured to dissipate energy from the charging antenna to prevent overheating of the charging antenna. The energy dissipating electric circuit may comprise one or more resistive elements.

The outer cover may comprise an outer cover electric interface. The outer cover electric interface may be electrically connected to the charging antenna. The case body may comprise an antenna connection electric interface. The antenna connection electric interface may be configured to electrically connect to the outer cover electric interface. The outer cover electric interface may be configured to be reversibly engaged and disengaged from the antenna connection electric interface.

According to a fifth aspect of the present invention, there is provided a charging case for an aerosol-generating device. The charging case comprises a case body and a housing part. The case body extends along an axial direction. The case body defines a docking compartment. The docking compartment is configured to receive an aerosol-generating device. The housing part is attached to the case body. The housing part forms at least part of an outer appearance of the charging case. The housing part comprises end cover portions. The end cover portions cover opposing ends of the case body along the axial direction. The housing part has an axially ending connection portion connecting the end cover portions.

The housing part may comprise a metal material. The housing part may consist of a metal material. The housing part may be formed as one piece. The housing part may be formed as one metal piece. The metal material may comprise aluminum. The material may be aluminum or an alloy of aluminum.

The charging case may further comprise an outer cover with a flexible flap portion. The flexible flap portion may be configured to reversibly wrap around the case body in a wrapping direction around the axial direction.

The outer cover may be removably attached to the case body. In particular, an attachment portion of the outer cover may be removably attached to the case body.

The outer cover, in particular the flexible flap portion of the outer cover, may have a free end. The free end may be configured to be attached to the case body to bring the outer cover into a storage configuration. The free end may be configured to be separated from the case body to bring the outer cover into an access configuration. The attachment portion of the outer cover may be attached to the case body both in the storage configuration and in the access configuration.

The outer cover may be configured to cover a loading opening of the docking compartment in the storage configuration.

The loading opening of the docking compartment may be uncovered in the access configuration.

The outer cover and the housing part may be configured to together define an entirety of an outer appearance of the charging case.

The outer cover may be configured to fully form an outer circumferential surface of the charging case, except for an axial slit through which the connection portion of the housing part is visible.

The connection portion may cover the case body. The connection portion may cover at least any portion of the case body that is not covered by the outer cover, at least in the storage configuration of the outer cover.

According to a sixth aspect of the present invention, there is provided a charging case for an aerosol-generating device. The charging case comprises a case body and an outer cover. The case body may extend along an axial direction. The case body defines a docking compartment. The docking compartment is configured to receive an aerosol-generating device. The outer cover is attached to the case body. The outer cover comprises a flexible flap portion. The flexible flap portion is configured toe reversibly wrap around the case body in a wrapping direction around the axial direction. The outer cover is configured to extend around the case body over at least 50 percent, or at least 60 percent, or at least 70 percent, or at least 80 percent, or at least 90 percent, or at least 100 percent of a circumference of the case body.

The circumference of the case body may be around the axial direction.

According to a seventh aspect of the present invention, an aerosol-generating system is provided. The aerosol-generating system comprises the charging case according to any one of the first, fourth, fifth or sixth aspects of the present invention. The aerosol-generating system further comprises the aerosol-generating device. The aerosol-generating device is configured to be received in the docking compartment of the charging case.

The aerosol-generating device may be a handheld electronic device. The aerosol-generating device may be essentially rod-shaped or essentially stick-shaped or essentially cylindrical, for example. When received in the docking compartment, a main extension direction of the aerosol-generating device may be parallel to the axial direction. The aerosol-generating device may be configured to be inserted into the docking compartment by moving the aerosol-generating device in a direction essentially perpendicular to the axial direction.

The aerosol-generating device may comprise a device battery. The device battery may be a rechargeable battery. The device battery may power one or more functions of the aerosol-generating device.

The aerosol-generating device may comprise a receiving cavity. The receiving cavity may be configured to receive an aerosol-generating article.

The aerosol-generating article may be configured to release aerosol upon being heated. The aerosol may be aerosol for consumption by a user.

The aerosol-generating article may be an essentially stick-shaped or rod-shaped article. The aerosol-generating article may comprise a plurality of segments arranged one behind the other. The segments may be cylinder-shaped segments arranged one behind the other along their longitudinal axis. The segments may be combined with one or more wrappers wrapped around the segments. The segments may comprise an aerosol-generating segment. The aerosol-generating segment may comprise an aerosol-generating material configured to release aerosol upon being heated. The aerosol-generating material may comprise tobacco. The segments may comprise a filter segment. Aerosol generated by heating the aerosol-generating segment may pass through the filter segment before reaching the mouth of a user. The segments may comprise a mouthpiece segment. The mouthpiece segment may be configured to be contacted by the mouth of a user. Alternatively, the filter segment may be engaged by the mouth of the user. One or both of the filter segment and the mouthpiece segment may protrude from the receiving cavity, when the aerosol-generating article is received in the aerosol-generating device.

The aerosol-generating device may comprise a heater. The heater may be configured to heat an aerosol-generating article received in the receiving cavity. The heater may, for example, comprise a resistive heater element. The resistive heater element may comprise a blade configured to penetrate into the aerosol-generating segment, when the aerosol-generating article is received into the receiving cavity. The heater may comprise an induction assembly configured to heat the aerosol-generating segment by induction heating of a susceptor incorporated in the aerosol-generating segment, in particular a metal susceptor. The device battery may power the heater.

The present disclosure comprises various aspects, embodiments, and examples. Features, advantages, and explanations disclosed with reference to any one of these aspects, embodiments, and examples may be combined with, or transferred to, any other one of the aspects, embodiments, and examples described herein. Any one of the charging cases or aerosol-generating systems described herein, in particular the charging cases according to the first, fourth, fifth and sixth aspects and the aerosol-generating system according to the seventh aspect, may be used in any one of the methods or uses described herein, in particular in the method according to the second aspect and in the use according to the third aspect. Features, advantages, and explanations described in the context of one the charging cases described herein, in particular in the context of any one of the charging cases according to the first, fourth, fifth and sixth aspects, may be combined with, or transferred to any one of the other charging cases described herein, in particular the charging cases according to any other one of the first, fourth, fifth or sixth aspects. The invention is defined in the claims. However, below there is provided a non-exhaustive list of non-limiting examples. Any one or more of the features of these examples may be combined with any one or more features of another example, embodiment, or aspect described herein.
Example Ex1: Charging case for an aerosol-generating device, comprising:
a case body extending along an axial direction and defining a battery compartment and a docking compartment, wherein the docking compartment is configured to receive an aerosol-generating device, and wherein the battery compartment is configured to removably receive a charging case battery; and
a battery compartment cover reversibly operable between a closed state and an open state, wherein the battery compartment cover is configured to cover a battery exchange opening of the battery compartment in the closed state and to allow access to the battery compartment through the battery exchange opening in the open state.
Example Ex2: Charging case according to Example Ex1, further comprising the charging case battery, wherein the charging case battery is removably arranged in the battery compartment.
Example Ex3: Charging case according to Example Ex1 or Ex2, wherein the battery compartment cover is attached to the case body in the closed state.
Example Ex4: Charging case according to any one of Examples Ex1 to Ex3, wherein the battery compartment cover is attached to the case body by one or more attachment elements.
Example Ex5: Charging case according to any one of Examples Ex1 to Ex4, wherein the battery compartment cover is removed from the case body in the open state.
Example Ex6: Charging case according to any one of Examples Ex1 to Ex5, wherein at least 50 percent, or at least 60 percent, or at least 70 percent, or at least 80 percent, or at least 90 percent of an area of the battery compartment cover is arranged above the battery exchange opening in the closed state.
Example Ex7: Charging case according to any one of Examples Ex1 to Ex6, wherein a maximum extension of the battery compartment cover beyond the battery exchange opening in the closed state is less than or equal to 40 millimeters, or 30 millimeters, or 25 millimeters, or 20 millimeters, or 15 millimeters, or 10 millimeters, or 5 millimeters.
Example Ex8: Charging case according to any one of Examples Ex1 to Ex7, wherein the battery compartment cover is plate-shaped.
Example Ex9: Charging case according to any one of Examples Ex1 to Ex8, wherein the battery compartment cover has a curvature in a sectional plane perpendicular to a longitudinal direction of the battery compartment cover and is non-curved along the longitudinal direction of the battery compartment cover.
Example Ex10: Charging case according to any one of Examples Ex1 to Ex9, wherein a surface of the case body has a recessed area, wherein the battery compartment cover is provided in the recessed area in the closed state.
Example Ex11: Charging case according to any one of Examples Ex1 to Ex10, wherein the battery compartment cover lies at least essentially flush with an adjacent surface of the case body in the closed state.
Example Ex12: Charging case according to any one of Examples Ex1 to Ex11, wherein the case body comprises a floor surface and a ceiling surface, the floor surface and the ceiling surface delimiting an extension of the battery compartment along the axial direction.
Example Ex13: Charging case according to any one of Examples Ex1 to Ex12, wherein the case body comprises a side surface forming an inner wall section of the battery compartment over an angular extension around a center axis of the battery compartment of at least 60 degrees, or at least 90 degrees, or at least 120 degrees, or at least 180 degrees, or at least 240 degrees. Example Ex14: Charging case according to Example Ex13, wherein the center axis is parallel to the axial direction.
Example Ex15: Charging case according to any one of Examples Ex1 to Ex14, wherein the battery compartment is accessible through the docking compartment.
Example Ex16: Charging case according to any one of Examples Ex1 to Ex15, wherein one or both of the battery compartment cover and the charging case battery is configured to be removed through the docking compartment after removal of the aerosol-generating device from the storage compartment.
Example Ex17: Charging case according to any one of Examples Ex1 to Ex16, wherein the battery exchange opening is formed in a wall defining an inner surface of the docking compartment.
Example Ex18: Charging case according to any one of Examples Ex1 to Ex17, wherein the battery compartment cover separates the battery compartment from the docking compartment in the closed state.
Example Ex19: Charging case according to any one of Examples Ex1 to E18, wherein a charging antenna for wirelessly charging the charging case battery is integrated in the battery compartment cover.
Example Ex20: Charging case according to Example Ex19, wherein the battery compartment cover comprises a battery compartment cover electric interface electrically connected to the charging antenna, and wherein the case body comprises a case body electric interface configured to be electrically connected to the charging case battery.
Example Ex21: Charging case according to Example Ex20, further comprising an electrical connector electrically connecting the battery compartment cover electric interface to the case body electric interface to supply power from the charging antenna to the charging case battery.
Example Ex 22: Charging case according to Example 21, wherein the electrical connector is a flexible connector.
Example Ex23: Charging case according to any one of Examples Ex1 to E22, wherein the battery compartment cover forms at least part of an outer appearance of the charging case.
Example Ex 24: Charging case according to any one of Examples Ex 1 to E 23, wherein the battery compartment cover comprises at least one of a user interface and a data port enabling data transmission between an external device and the charging case.
Example Ex25: Charging case according to any one of Examples Ex1 to E24, wherein the battery compartment cover comprises a metal material or is formed of a metal material.
Example Ex26: Charging case according to any one of Examples Ex1 to E25, wherein the battery compartment cover comprises end portions covering opposing ends of the case body with respect to the axial direction.
Example Ex27: Charging case according to Example Ex26, wherein at least one of the end portions has a curved side surface defining at least a part of a side surface of the charging case extending around the axial direction.
Example Ex28: Charging case according to Example Ex26 or Ex27, wherein battery compartment cover has an axially extending cover portion connecting the end portions.
Example Ex29: Charging case according to any one of Examples Ex1 to E28, wherein the battery compartment cover defines a cavity receiving the battery compartment in the closed state of the battery compartment cover.
Example Ex30: Charging case according to any one of Examples Ex1 to E29, wherein the case body is at least partially received in the battery compartment cover in the closed state of the battery compartment cover.
Example Ex31: Charging case according to any one of Examples Ex1 to Ex30, further comprising an outer cover configured to form at least part of an outer surface of the charging case, wherein the outer cover is configured to cover the battery compartment cover.
Example Ex32: Charging case according to Example Ex31, wherein the outer cover is removably attached to the case body.
Example Ex33: Charging case according to Example Ex31 or Ex32, wherein the outer cover is configured to wrap around the case body from one side of the case body around the opposing side of the case body back to the one side of the case body.
Example Ex34: Charging case according to any one of Examples Ex31 to Ex33, wherein the outer cover comprises a flexible flap portion configured to reversibly wrap around the case body.
Example Ex35: Charging case according to any one of Examples Ex31 to Ex34, wherein the outer cover has a free end, wherein the free end is configured to be attached to the case body to bring the outer cover into a storage configuration and configured to be separated from the case body to bring the outer cover into an access configuration.
Example Ex36: Charging case according to Example Ex35, wherein the outer cover is configured to cover a loading opening of the docking compartment in the storage configuration.
Example Ex37: Charging case according to Example Ex35 or Ex36, wherein the loading opening of the docking compartment is uncovered in the access configuration.
Example Ex38: Charging case according to any one of Examples Ex31 to Ex37, wherein the outer cover is configured to extend around the case body over at least 50 percent, or at least 60 percent, or at least 70 percent, or at least 80 percent, or at least 90 percent, or between 95 percent and 99 percent, or at least 100 percent of a circumference of the case body.
Example Ex39: Charging case according to any one of Examples Ex31 to Ex38, wherein a charging antenna for wirelessly charging the charging case battery is integrated in the outer cover.
Example Ex40: Charging case according to Example Ex39, wherein the outer cover comprises a stiffening layer where the charging antenna is integrated in the outer cover.
Example Ex41: Charging case according to Example Ex39 or Ex40, wherein the outer cover comprises an outer cover electric interface electrically connected to the charging antenna, and wherein the case body comprises an antenna connection electric interface configured to electrically connect to the outer cover electric interface.
Example Ex42: Charging case according to any one of Examples Ex1 to Ex41, further comprising a housing part attached to the case body, wherein the housing part forms at least part of an outer appearance of the charging case.
Example Ex43: Charging case according to Example Ex42, wherein the housing part comprises end cover portions covering opposing ends of the case body with respect to the axial direction.
Example Ex44: Charging case according to Example Ex43, wherein at least one of the end cover portions has a side surface defining at least a part of a side surface of the charging case extending around the axial direction, wherein the side surface is curved.
Example Ex45: Charging case according to Example Ex43 or Ex44, further comprising a display provided in a display receiving cavity of at least one of the end cover portions.
Example Ex46: Charging case according to any one of Examples Ex43 to Ex45, wherein the housing part has an axially extending connection portion connecting the end cover portions. Example Ex47: Charging case according to any one of Examples Ex42 to Ex46, wherein the housing part comprises a metal material.
Example Ex48: Method for replacing a battery of a charging case for an aerosol-generating device, comprising:
a) removing a battery compartment cover from a case body of the charging case, thereby uncovering a battery exchange opening of a battery compartment of the charging case;
b) removing a charging case battery from the battery compartment through the battery exchange opening;
c) inserting a replacement charging case battery into the battery compartment through the battery exchange opening; and
d) re-attaching the battery compartment cover to the case body to close the battery compartment.
Example Ex49: Method according to Example Ex48, wherein removing the battery compartment cover from the case body comprises disengaging one or more attachment elements fixing the battery compartment cover to the case body.
Example Ex50: Method according to Example Ex48 or Ex49, wherein at least one of the battery compartment cover and the charging case battery is removed through a loading opening configured to insert an aerosol-generating device into a docking compartment of the charging case.
Example Ex51: Method according to any one of Examples Ex48 to Ex50, further comprising removing an outer cover of the charging case from the case body to uncover the battery compartment cover.
Example Ex52: Method according to any one of Examples Ex48 to Ex51, wherein removing the outer cover of the charging case comprises overcoming magnetic attraction holding the outer cover at the case body.
Example Ex53: Method according to any one of Examples Ex48 to Ex52, wherein removing the battery compartment cover from the case body comprises removing the case body from a cavity of the battery compartment cover.
Example Ex54: Use of an outer cover for covering a removable battery compartment cover of a charging case for an aerosol-generating device.
Example Ex55: Use according to Example Ex54, wherein the outer cover defines an outer appearance of the charging case over a full circumference of the charging case around an axial direction.
Example Ex56: Use according to Example Ex54 or Ex55, wherein the outer cover is removably attached to a case body defining the battery compartment.
Example Ex57: Use according to any one of Examples Ex54 to Ex56, wherein the outer cover comprises a flexible flap portion for covering a loading opening of a docking space of the charging case, wherein the docking space is configured to receive an aerosol-generating device to be charged.
Example Ex58: Use according to any one of Examples Ex54 to Ex57, wherein the outer cover comprises a rigid cover portion, wherein the rigid cover portion covers the battery compartment cover.
Example Ex59: Charging case for an aerosol-generating device, comprising:
a case body extending along an axial direction and defining a docking compartment configured to receive an aerosol-generating device;
a charging case battery; and
an outer cover configured to form at least part of an outer surface of the charging case;
wherein a charging antenna for wirelessly charging the charging case battery is integrated in the outer cover.
Example Ex60: Charging case according to Example Ex59, wherein the outer cover is removably attached to the case body.
Example Ex 61: Charging case according to Example Ex59 or Ex 60, wherein the outer cover comprises a flexible flap portion configured to reversibly wrap around the case body.
Example Ex62: Charging case according to any one of Examples Ex59 to Ex61, wherein the outer cover has a free end, wherein the free end is configured to be attached to the case body to bring the outer cover into a storage configuration and configured to be separated from the case body to bring the outer cover into an access configuration.
Example Ex63: Charging case according to Example Ex62, wherein the outer cover is configured to cover a loading opening of the docking compartment in the storage configuration.
Example Ex64: Charging case according to Example Ex62 or Ex63, wherein the loading opening of the docking compartment is uncovered in the access configuration.
Example Ex65: Charging case according to any one of Examples Ex59 to Ex64, wherein the outer cover comprises a stiffening layer where the charging antenna is integrated in the outer cover.
Example Ex66: Charging case according to any one of Examples Ex59 to Ex65, wherein the outer cover comprises an energy dissipating electric circuit configured to dissipate energy from the charging antenna to prevent overheating of the charging antenna.
Example Ex67: Charging case according to any one of Examples Ex59 to Ex66, wherein the outer cover comprises an outer cover electric interface electrically connected to the charging antenna, and wherein the case body comprises an antenna connection electric interface configured to electrically connect to the outer cover electric interface
Example Ex68: Charging case for an aerosol-generating device, comprising:
a case body extending along an axial direction and defining a docking compartment configured to receive an aerosol-generating device; and
a housing part attached to the case body, wherein the housing part forms at least part of an outer appearance of the charging case;
wherein the housing part comprises end cover portions covering opposing ends of the case body along the axial direction;
wherein the housing part has an axially extending connection portion connecting the end cover portions.
Example Ex69: Charging case according to Example Ex68, wherein the housing part comprises a metal material.
Example Ex70: Charging case according to Example Ex68 or Ex69, further comprising an outer cover with a flexible flap portion configured to reversibly wrap around the case body in a wrapping direction around the axial direction.
Example Ex71: Charging case according to Example Ex70, wherein the outer cover is removably attached to the case body.
Example Ex72: Charging case according to Example Ex70 or Ex71, wherein the outer cover has a free end, wherein the free end is configured to be attached to the case body to bring the outer cover into a storage configuration and configured to be separated from the case body to bring the outer cover into an access configuration.
Example Ex73: Charging case according to Example Ex72, wherein the outer cover is configured to cover a loading opening of the docking compartment in the storage configuration. Example Ex74: Charging case according to Example Ex72 or 73, wherein the loading opening of the docking compartment is uncovered in the access configuration.
Example Ex75: Charging case according to any one of Examples Ex70 to Ex74, wherein the outer cover and the housing part are configured to together define an entirety of an outer appearance of the charging case.
Example Ex76: Charging case according to any one of Examples Ex70 to Ex75, wherein the outer cover is configured to fully form an outer circumferential surface of the charging case, except for an axial slit through which the connection portion of the housing part is visible.
Example Ex77: Charging case for an aerosol-generating device, comprising:
a case body extending along an axial direction and defining a docking compartment configured to receive an aerosol-generating device; and
an outer cover attached to the case body and comprising a flexible flap portion configured to reversibly wrap around the case body in a wrapping direction around the axial direction;
wherein the outer cover is configured to extend around the case body over at least 50 percent, or at least 60 percent, or at least 70 percent, or at least 80 percent, or at least 90 percent, or at least 100 percent of a circumference of the case body.
Example Ex78: Aerosol-generating system, comprising:
the charging case according to any one of Examples Ex1 to Ex47, or Ex59 to Ex77; and
an aerosol-generating device;
wherein the aerosol-generating device is configured to be received in the docking compartment of the charging case.

Examples will now be further described with reference to the figures, in which:

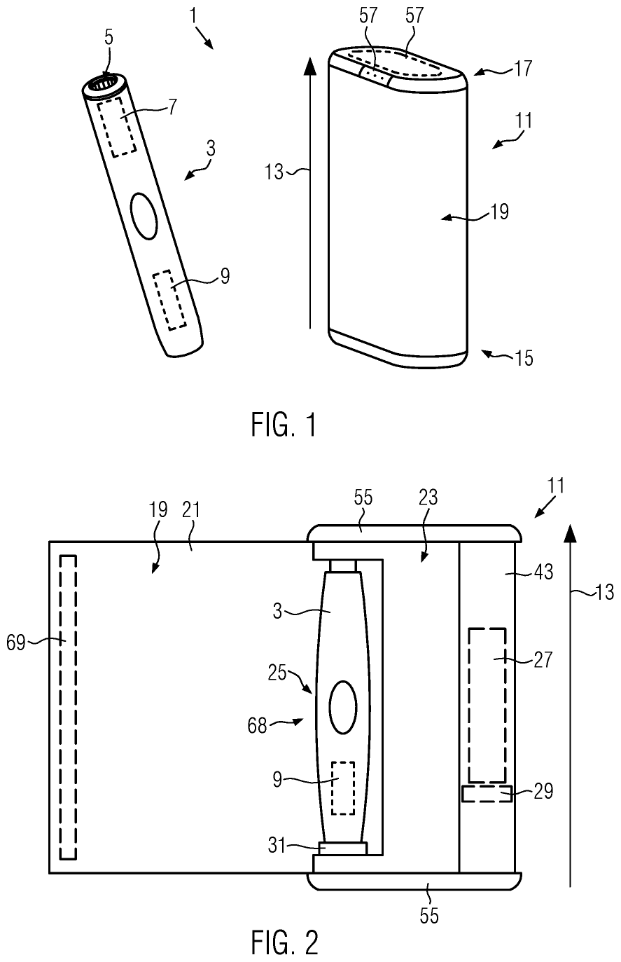

FIG. 1 shows a schematic perspective view of an aerosol-generating system according to a first embodiment;

FIG. 2 shows a schematic side view of the aerosol-generating system according to the first embodiment in an access configuration;

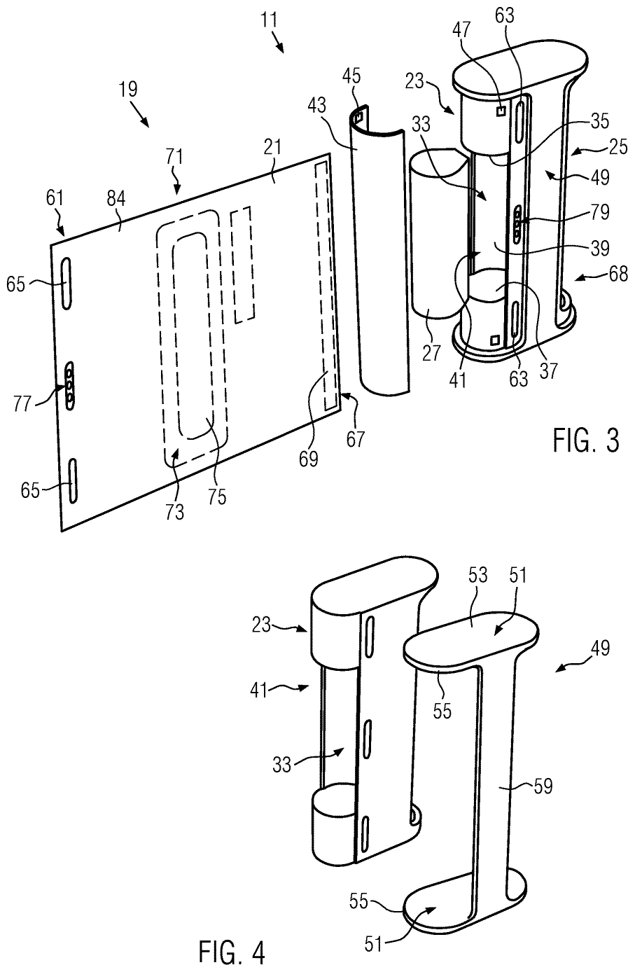

FIG. 3 shows a schematic perspective view of a charging case of the aerosol-generating system according to the first embodiment in a partially disassembled state;

FIG. 4 shows a schematic perspective view of a case body and a housing part of the charging case of the aerosol-generating system according to the first embodiment;

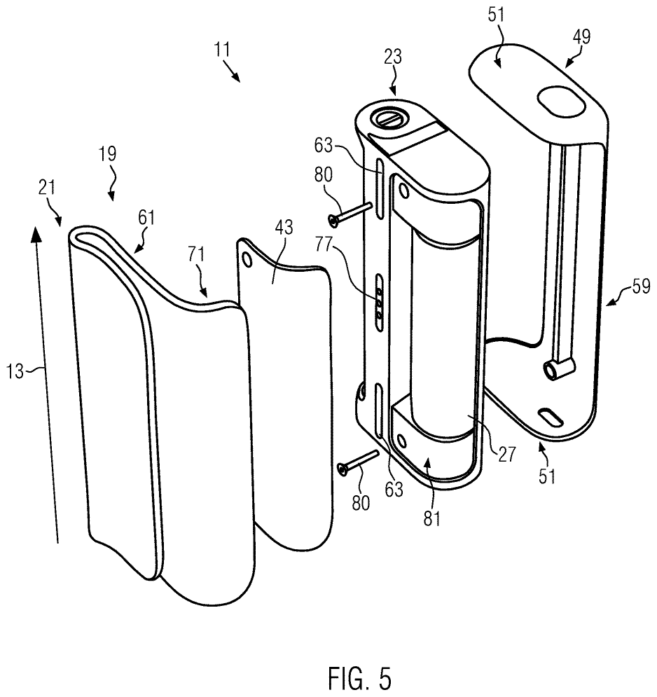

FIG. 5 shows a schematic perspective view of a charging case according to a second embodiment in a partially disassembled state;

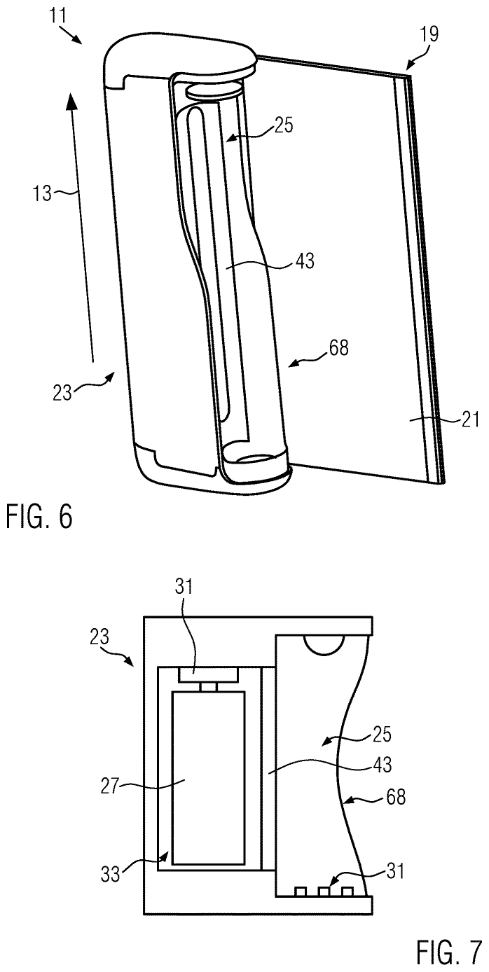

FIG. 6 shows a perspective view of a charging case according to a third embodiment in an access configuration;

FIG. 7 shows a schematic sectional view of the charging case according to the third embodiment without showing the outer cover;

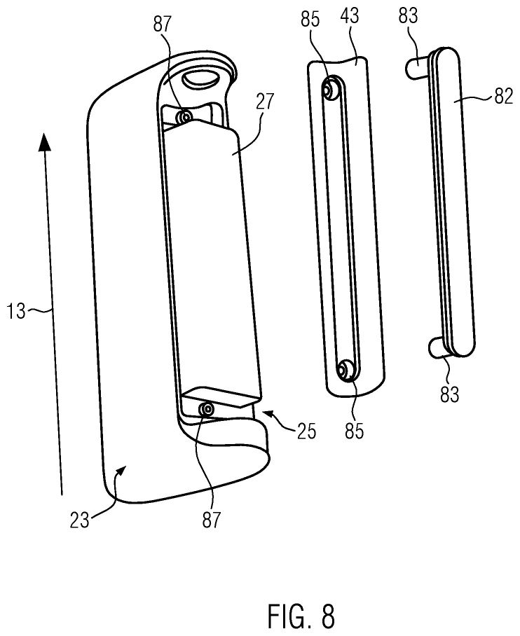

FIG. 8 shows a schematic perspective view of the charging case according to the third embodiment without showing the outer cover in a partially disassembled state;

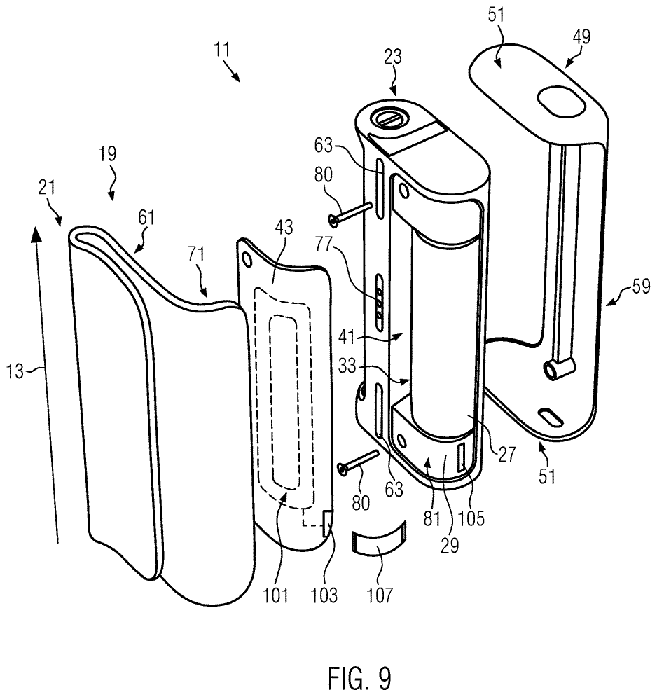

FIG. 9 shows a schematic perspective view of a charging case according to a fourth embodiment in a partially disassembled state; and

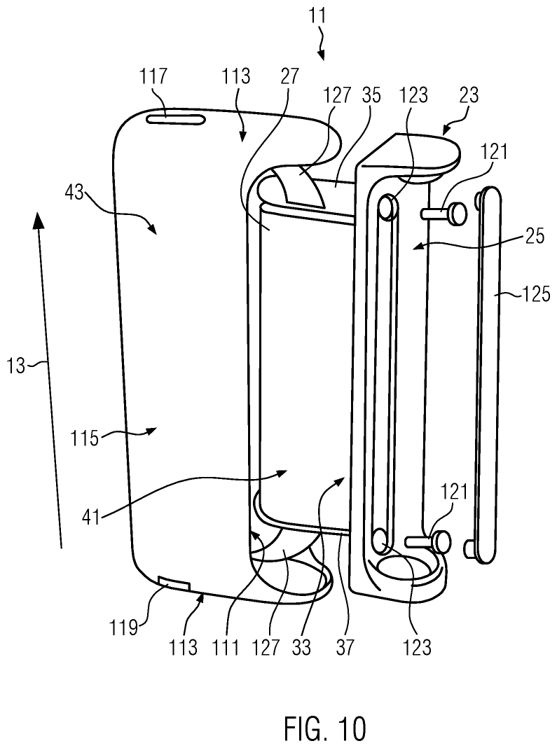

FIG. 10 shows a schematic perspective view of a charging case according to a fifth embodiment in a partially disassembled state.

Like features are indicated with like reference numerals throughout the claims.

FIG. 1 shows an aerosol-generating system 1 according to a first embodiment. The aerosol-generating system 1 comprises an aerosol-generating device 3. The aerosol-generating device 3 can be a handheld electronic device for heating a stick-shaped aerosol-generating article (not shown) to produce an aerosol for consumption by a user. The aerosol-generating device 3 comprises a receiving cavity 5 for receiving the aerosol-generating article. The aerosol-generating device 3 further comprises a heater 7 to heat the aerosol-generating article, in particular an aerosol-generating segment of the aerosol-generating article. The heater 7 may, for example comprise a resistive heater element or an induction heating assembly configured to heat the aerosol-generating segment of the aerosol-generating article. The aerosol-generating device 3 further comprises a rechargeable device battery 9 for electrically powering one or more functions of the aerosol-generating device 3. For example, the device battery 9 can power the heater 7.

The aerosol-generating system 1 further comprises a charging case 11. The charging case 11 extends along an axial direction 13 from a first end 15 of the charging case 11 to a second end 17 of the charging case 11. A main extension direction of the charging case 11 is along the axial direction 13.

The charging case 11 comprises an outer cover 19. In FIG. 1, the charging case 11 is shown with the outer cover 19 in a storage or closed configuration. FIG. 2 shows the charging case 11 with the outer cover 19 in an access or open configuration.

As shown in FIG. 2, the charging case 11 further comprises a case body 23. The case body 23 extends along the axial direction 13 and defines a docking compartment 25. The docking compartment 25 is configured to removably receive the aerosol-generating device 3. A user may store or insert the aerosol-generating device 3 in or to the docking compartment 25 of the charging case 11, for example between uses. Case body 23 can be removably insertable into housing part 49, and can include electronics for charging battery 9, and electronics for charging battery 27.

The charging case 11 comprises a charging case battery 27. The charging case battery 27 is in electrical contact with an electric battery interface 29 of the charging case 11. The electric battery interface 29 is electrically connected to an electric device interface 31 provided in the docking compartment 25, for example via an electronic circuit for charging the device battery 9. When the aerosol-generating device 3 is received in the docking compartment 25, the aerosol-generating device 3 can be electrically connected with the electric device interface 31 to allow charging of the device battery 9 with electrical energy that can originate from the charging case battery 27. Thus, the device battery 9 may be recharged between uses, while stored in the docking compartment 25.

As best shown in FIG. 3, the charging case battery 27 is received in a battery compartment 33 defined by the case body 23. The case body 23 has a ceiling surface 35 and a floor surface 37 delimiting the battery compartment 33 along the axial direction 13.

Further, the case body 23 has a side wall 39 extending along the axial direction 13 between the ceiling surface 35 and the floor surface 37. The ceiling surface 35, the floor surface 37, and the side surface 39 together define the battery compartment 33. The battery compartment 33 has a battery exchange opening 41, through which the charging case battery 27 may be inserted into the battery compartment 33 or removed from the battery compartment 33. Battery compartment can 33 can include additional features for aiding the removal of the charging case battery 27, for example a ribbon or strip of fabric that can partially wrap around an inserted charging case battery 27, so that the inserted charging case battery 27 can be pulled out via the ribbon or strip. Generally, the battery compartment 33 and corresponding compartment cover 43 described herein is configured that a charging case battery 27 can be easily removed and inserted thereto by the user, without requiring specialized tooling or a destructive or irreversible process, for example the braking of casing walls, cutting of wired connections to battery, to allow a user to replace the charging case battery once it becomes defective or has insufficient capacity.

The charging case 11 can further comprise a battery compartment cover 43. The battery compartment cover 43 is operable between a closed state and an open state. The closed state is shown in FIG. 2. In the closed state, the battery compartment cover 43 covers the battery exchange opening 41 so that the charging case battery 27 within the battery compartment 33 is not accessible to be removed through the battery exchange opening 41. The open state is shown in FIG. 3. In the open state, the battery compartment cover 43 allows access to the battery compartment 33 though the battery exchange opening 41 to remove or insert the charging case battery 27. In the closed state, the battery compartment cover 43 is attached to the case body 23. In the open state, the battery compartment cover is removed from the case body 23.

In the first embodiment, the battery compartment cover 43 is reversibly attachable to the case body 23 with a snap-fit connection. The snap-fit connection comprises structures 45 provided at the battery compartment cover 43 and corresponding counter-structures 47 provided at the case body 23. The structures 45 are configured to engage corresponding the counter-structures 47. For example, one of the structures 45 and the counter structures 47 may comprise hook structures and the other one of the structures 45 and the counter structures 47 may comprise recesses receiving the hook-structures. The hook structures may be deformable, for by having a tab or surface that can be engaged with a tool or a finger of a user for bending the hook-structures, to allow destruction-free removal of the battery compartment cover 43 from the case body 23.

Alternatively, or additionally, the battery compartment cover 43 may be reversibly attached to the case body 23 by one or more attachment elements that are separate from the battery compartment cover 43 and the case body 23, such as screws, pins, snap fasteners, velcro-like surfaces.

The battery compartment cover 43 can be plate-shaped. The battery compartment cover 43 can comprise a curvature in a sectional plane perpendicular to the axial direction 13. In addition, the battery compartment cover 43 can be non-curved along the axial direction 13. As shown in FIG. 3, for example, a curvature of the battery compartment cover 43 corresponds to a curvature of the case body 23.

As best shown in FIGS. 3 and 4, the charging case 11 comprises a housing part 49 attached to the case body 23. The housing part 49 can be a one-piece metal structure. The housing part 49 can form at least part of an outer appearance of the charging case 11. The housing part 49 comprises end cover portions 51 forming end surfaces of the charging case 11 with respect to the axial direction 13. The end cover portions 51 essentially extend perpendicular to the axial direction 13. The end cover portions 51 each comprise an end surface 53 visible, when viewing the charging case 11 along or against the axial direction 13. Further, the end cover portions 51 each comprise a side surface 55 visible when viewing the charging case 11 in a viewing direction perpendicular to the axial direction 13. The side surfaces 55 may form edge portions of the charging case 11 at the first end 15 and the second end 17 of the charging case 11, respectively. The edge portions can be formed as rounded, smooth surfaces. In a sectional plane parallel to the axial direction 13, the side surfaces 55 of the end cover portions 51 are curved. The housing part 49 can also comprise a connection portion 59 extending in parallel to the axial direction 13 and connecting the end cover portions 51 to each other. For example, the housing part 49 comprising the connection portion 59 together with the two end cover portions 51 may be made of a single aluminum or aluminum alloy cast element, forming a frame for holding case body 23 that can be located between the two end cover portions 51.

As shown in FIG. 1, a display 57 may be received in a receiving cavity of at least one end cover portion 51. In particular, the receiving cavity may be provided in the side surface 55 of the end cover portion 51. The display 57 may be also curved. A curvature of the display 57 may be the same as the curvature of the side surface 55 of the end cover portion 51. The display 57 may lie flush with a surface of the end cover portion 51. The display 57 may, for example, indicate a charging state of the charging case battery 27 or the device battery 9, and may be able to display other information related to an operational status of the aerosol generating system 1. In a variant, which is shown in broken lines in FIG. 1, it is also possible that a substantial area of one of the end cover portions 51 is covered by the display 57, for example such that the display 57 is arranged in a center of the end cover portion 51, forming a curved display screen, and there is a small surrounding border that is made of the end cover portion 51, or that the entire end cover portion 51 is covered by the display 57. The display 57 may have an oval shape, or a longitudinal shape with two curved side edges. The display 57 may comprise a curved high-resolution screen.

The outer cover 19 can be removably attached to the case body 23. FIG. 3 shows the outer cover 19 removed from the case body 23. The outer cover 19 comprises a connection portion 61 to be removably attached to the case body 23. Preferably, the connection portion 61 of the outer cover 19 is attachable to the case body 23 by magnetic interaction. Magnets 63 are provided at the case body 23 to magnetically interact with corresponding magnets 65 provided in the connection portion 61 of the outer cover 19. Alternatively, the magnets 63 of the case body 23 or the magnets 65 of the outer cover 19 may be replaced metallic structures susceptible to magnetic interaction.

The outer cover 19 comprises a flexible flap portion 21. The flexible flap portion 21 comprises a free end 67 of the outer cover 19. The free end 67 may extend in parallel to the axial direction 13. The flexible flap portion 21 is configured to reversibly wrap around the case body 23, while the outer cover 19 is attached to the case body 23 at the connection portion 61. At the free end 67 of the flexible flap portion 21, a latch part 69 is provided. The latch part 69 is configured to reversibly attach to the case body 23. Preferably, the latch part 69 comprises a magnet incorporated into the outer cover 19, or attached to the outer cover 19. The free end 67 may be attached to the case body 23 to bring the outer cover 19 into a storage configuration. The storage configuration is shown in FIG. 1. In the storage configuration, the outer cover 19 covers a loading opening 68 of the docking compartment 25. The outer cover 19 may be brought into an access configuration by separating the free end 67 of the flexible flap portion 21 from the case body 23, and by bending or moving the flexible flap portion 21 away from the docking compartment 25. In the access configuration, the loading opening 68 of the docking compartment 25 is accessible to insert the aerosol-generating device 3 into the docking compartment 25 or to remove the aerosol-generating device 3 from the docking compartment 25.

As shown in FIG. 3, the outer cover 19 comprises a rigid cover portion 71 between the connection portion 61 and the flexible flap portion 21. The rigid cover portion 71 can cover a portion of the case body 3 that is non-curved around the axial direction 13. A stack 73 of layers can be integrated in the rigid portion 71 of the outer cover 19. The stack 73 of layers can comprise a stiffening layer to reduce bendability of the rigid portion 71, a wireless charging antenna 75 on top of the stiffening layer, and a heat dissipation layer on top of the wireless charging antenna 75, the heat dissipation layer being the layer that is closest to the outside environment. The stiffening layer may reduce a risk that the wireless charging antenna 75 is damaged due to bending of the outer cover 19 in the region of the wireless charging antenna 75. The heat dissipating layer may improve heat dissipation to the outside to reduce a risk that the outer cover 19 or the wireless charging antenna 75 is damaged due to excess heat generated by the wireless charging antenna 75, in particular in a state of the outer cover 19 being removed from the case body 23.

In the connection portion 61 of the outer cover 19, an outer cover electric interface 77 can be provided. The outer cover electric interface 77 can be electrically connected to the charging antenna 75 for electric interconnection and operability with the case body 23. The case body 23 comprises an antenna connection electric interface 79. When the outer cover 19 is attached to the case body 23, the outer cover electric interface 77 electrically connects to the antenna connection electric interface 79. In combination with a suitable wireless charging station, the wireless charging antenna 75 may charge the charging case battery 27.

As shown in FIG. 3, the outer cover 19 may comprise a second flexible flap portion 84. The second flexible flap portion 84 may be provided between the connection portion 61 and the rigid cover portion 71. The rigid cover portion 71 may be provided between the flexible flap portion 21 and the second flexible flap portion 84.

FIG. 5 shows a charging case 11 according to a second embodiment. The principle concept of the charging case 11 according to the second embodiment is similar to that of the charging case 11 of the first embodiment. Thus, a description of same or similar aspects is omitted and the description concentrates on differences with respect to the first embodiment.

In the second embodiment, the battery compartment cover 43 is reversibly attachable to the case body 23 by external attachment elements 80, for example in the form of screws.

In the closed state, the battery compartment cover 43 is received in a recessed area 81 of the case body 23. Thus, in the closed state, the battery compartment cover 43 lies flush with adjacent surfaces of the case body 23.

In the outer cover 19, according to the second embodiment, the connection portion 61 with the magnets 65 and the outer cover electric interface 77 is provided between the flexible flap portion 21 and the rigid portion 71. The rigid portion 71 is curved in line with the curvature of the case body 23. When the outer cover 19 is attached to the case body 23, the rigid portion 71 lies above the charging case cover 43.

In the second embodiment, the outer cover 19 does not extend around a full circumference of the charging case 11 in the storage configuration. Rather, the connection portion 59 of the housing part 49 is at least partially visible. Around the axial direction 13, an outer appearance of the charging case 11 is formed by the outer cover 19 and the connection portion 59 of the housing part 49 together.

FIGS. 6 to 8 show a charging case 11 according to a third embodiment. The principle concept of the charging case 11 according to the third embodiment is similar to that of the charging cases of the first and second embodiments. Thus, a description of same or similar aspects is omitted and the description concentrates on differences with respect to the first and second embodiments.

In the third embodiment, a removable part of an inner wall of the docking compartment 25 forms the battery compartment cover 43. As illustrated in FIG. 8, the battery compartment cover 43 may be removed, when the aerosol-generating device 3 is not inserted in the docking compartment 25. After the battery compartment cover 43 has been removed, the charging case battery 27 may be removed from the battery compartment 33 through the docking compartment 25. The battery compartment cover 43 is reversibly attachable to the case body 23 with an attachment element in the form of a clip 82. The clip 82 comprises two protrusions 83 configured to extend through corresponding openings 85 in the battery compartment cover 43 to engage receiving structures 87 of the case body 23. With this embodiment, it is possible to conceal a battery compartment cover 43 within the already existing docking compartment 25, specifically to be not readily visible when the aerosol-generating device 3 is inserted, thereby only minimally visually impacting the design for the removable battery arrangement.

As shown in FIG. 7, the battery compartment cover 43 separates the docking compartment 25 from the battery compartment 33. The battery compartment cover 43 may be removed through the docking compartment 25. The charging case battery 27 may be removed from the battery compartment 33 through the docking compartment 25.

FIG. 9 shows a charging case 11 according to a fourth embodiment. The principle concept of the charging case 11 according to the fourth embodiment is similar to that of the charging cases of the first to third embodiments. Thus, a description of same or similar aspects is omitted and the description concentrates on differences with respect to the first to third embodiments.

The fourth embodiment corresponds to the second embodiment shown in FIG. 5, except that in the fourth embodiment there is a charging antenna 101 integrated in the battery compartment cover 43 to enable wireless charging of the charging case battery 27 from an external wireless charging station.

The charging antenna 101 is electrically connected to a battery compartment cover electric interface 103 of the battery compartment cover 43. The case body 23 comprises a case body electric interface 105 electrically connected to the charging case battery 27 via the electric battery interface 29. The charging case 11 comprises an electrical connector 107 electrically connecting the battery compartment cover electric interface 103 to the case body electric interface 105 to supply power from the charging antenna 101 integrated in the battery compartment cover 43 to the charging case battery 27. In the illustrated embodiment, the electrical connector 107 is a flexible connector. Due to the flexibility of the electrical connector 107, there is no need to detach the electrical connector 107 from any one of the battery compartment cover electric interface 103 and the case body electric interface 105, when the battery compartment cover 43 is removed to access the charging case battery 27.

FIG. 10 shows a charging case 11 according to a fifth embodiment. The principle concept of the charging case 11 according to the fifth embodiment is similar to that of the charging cases of the first to fourth embodiments. Thus, a description of same or similar aspects is omitted and the description concentrates on differences with respect to the first to fourth embodiments.

As in the previous embodiments, the charging case 11 of the fifth embodiment comprises a case body 23 and a battery compartment cover 43. The case body 23 extends along the axial direction 13 and defines a docking compartment 25 for an aerosol-generating device 3. The case body 23 further defines a battery compartment 33 receiving the charging case battery 27. The case body 23 has a ceiling surface 35 and a floor surface 37 delimiting the battery compartment 33 along the axial direction 13.

FIG. 10 shows the charging case 11 with the battery compartment cover 43 in the open state with the battery exchange opening 41 of the battery compartment 33 being accessible. Operating the battery compartment cover 43 from the closed state to the open state may comprise partially or fully removing the case body 23 from a cavity 111 of the battery compartment cover 43. By at least partially removing the case body 23 from the cavity 111, the battery compartment 33 becomes accessible to enable removal of the charging case battery 27 from the battery compartment 33.

To operating the battery compartment cover 43 from the open state to the closed state, the case body 23 may be partially or fully inserted into the cavity 111. By inserting the case body 23 into the cavity 111, the battery compartment 33, and in particular the battery exchange opening 41 of the battery compartment 33, may become covered by the battery compartment cover 43. In the closed state of the battery compartment cover 43, the case body 23 is at least partially received in the battery compartment cover 43, in particular in the cavity 111 of the battery compartment cover 43.

In the closed state of the battery compartment cover 43, the case body 23 may be fixed to the battery compartment cover 43 by removably attachment elements 121, such as screws extending through screw holes 123 in the case body 23. The charging case 11 may comprise a fixing element cover 125 removably arranged at the case body 23 to cover the attachment elements 121 in the closed state of the battery compartment cover 43.

The battery compartment cover 43 comprises end portions 113 covering opposing ends of the case body 23 with respect to the axial direction 13 in the closed state of the battery compartment cover 43. The end portions 113 form part of an outer appearance of the charging case 11. The end portions 113 may have curved side surfaces defining at least a part of a side surface of the charging case 11 extending around the axial direction 13. The battery compartment cover 43 further has an axially extending cover portion 115 connecting the end portions 113. The axially extending cover portion 115 is curved around the axial direction 13.

In the fifth embodiment, the battery compartment cover 43 forms a considerable part of an outer appearance of the charging case 11.

The battery compartment cover 43 may comprise a user interface 117 facilitating user interaction with the charging case 11. The user interface 117 may comprise a display or a push button, for example. The battery compartment cover 43 may comprise a data port 119 enabling data transmission between an external device and the charging case 111. The data port 119 may comprise a USB port, in particular a USB-C port, for example. The user interface 117 and/or the data port 119 may be connected to the case body 23 by flexible connectors 127, for example.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A ±{10 percent} of A. Within this context, a number A may be considered to include numerical values that are within general standard error for the measurement of the property that the number A modifies. The number A, in some instances as used in the appended claims, may deviate by the percentages enumerated above provided that the amount by which A deviates does not materially affect the basic and novel characteristic(s) of the claimed invention. Also, all ranges include the maximum and minimum points disclosed and include any intermediate ranges therein, which may or may not be specifically enumerated herein.

1.-15. (canceled)

16. A charging case for an aerosol-generating device, comprising:
a case body extending along an axial direction and defining a battery compartment and a docking compartment, wherein the docking compartment is configured to receive an aerosol-generating device, and wherein the battery compartment is configured to removably receive a charging case battery;
a battery compartment cover reversibly operable between a closed state and an open state, wherein the battery compartment cover is configured to cover a battery exchange opening of the battery compartment in the closed state and to allow access to the battery compartment through the battery exchange opening in the open state; and
an outer cover comprising a flexible flap portion configured to reversibly wrap around the case body, wherein the outer cover is configured to form at least part of an outer surface of the charging case, and wherein the outer cover is further configured to cover the battery compartment cover.

17. The charging case according to claim 16, wherein the battery compartment cover is plate-shaped.

18. The charging case according to claim 16,
wherein a surface of the case body has a recessed area, and
wherein the battery compartment cover is provided in the recessed area in the closed state.

19. The charging case according to claim 16, wherein the battery compartment is accessible through the docking compartment.

20. The charging case according to claim 16, wherein the battery exchange opening is formed in a wall defining an inner surface of the docking compartment.

21. The charging case according to claim 16, wherein the battery compartment cover separates the battery compartment from the docking compartment in the closed state.

22. The charging case according to claim 16, wherein the outer cover is removably attached to the case body.

23. The charging case according to claim 16, wherein the outer cover is configured to wrap around the case body from one side of the case body around an opposing side of the case body back to the one side of the case body.

24. The charging case according to claim 16, wherein a charging antenna configured for wirelessly charging the charging case battery is integrated in the outer cover.

25. The charging case according to claim 16, wherein a charging antenna configured for wirelessly charging the charging case battery is integrated in the battery compartment cover.

26. The charging case according to claim 16, wherein the battery compartment cover defines a cavity receiving the battery compartment in the closed state of the battery compartment cover.

27. The charging case according to claim 16, further comprising a housing part attached to the case body,
wherein the housing part forms at least part of an outer appearance of the charging case, and
wherein the housing part comprises end cover portions covering opposing ends of the case body with respect to the axial direction.

28. A method for replacing a battery of a charging case for an aerosol-generating device, the method comprising:
a) removing an outer cover of the charging case from a case body of the charging case to uncover a battery compartment cover, wherein the outer cover comprises a flexible flap portion configured to reversibly wrap around the case body;
b) removing the battery compartment cover from the case body, thereby uncovering a battery exchange opening of a battery compartment of the charging case;
c) removing a charging case battery from the battery compartment through the battery exchange opening;
d) inserting a replacement charging case battery into the battery compartment through the battery exchange opening; and
e) reattaching the battery compartment cover to the case body to close the battery compartment.

29. The method according to claim 28, wherein at least one of the battery compartment cover and the charging case battery is removed through a loading opening configured to insert an aerosol-generating device into a docking compartment of the charging case.

30. An outer cover for covering a removable battery compartment cover of a charging case for an aerosol-generating device, the outer cover comprising:
a flexible flap portion configured to cover a loading opening of a docking space of the charging case,
wherein the docking space is configured to receive an aerosol-generating device to be charged.
